(19) United States
(12) Patent Application Publication
(10) Pub. No.: US 2025/0098199 A1
(43) Pub. Date: Mar. 20, 2025

(54) Corrosion Resistant Metal Structures for Wide Bandgap Semiconductor Devices

(71) Applicant: Wolfspeed, Inc., Durham, NC (US)

(72) Inventors: Kyle Bothe, Cary, NC (US); Evan Bertrue Jones, Durham, NC (US); Daniel Kevin Etter, Durham, NC (US)

(21) Appl. No.: 18/471,003

(22) Filed: Sep. 20, 2023

(51) Int. Cl. H01L 29/778; H01L 29/16; H01L 29/20; H01L 29/40; H01L 29/45; H01L 29/872

(52) U.S. Cl. CPC H10D 30/475; H10D 8/60; H10D 62/8325; H10D 62/85; H10D 62/8503; H10D 64/111; H10D 64/62

(57) ABSTRACT

Semiconductor devices are provided. In one example, the semiconductor device includes a wide bandgap semiconductor structure. The semiconductor device includes a metal structure on the wide bandgap semiconductor structure. The metal structure has a metal layer. The metal layer has a metal selected from the group consisting of ruthenium, osmium, rhodium, or iridium.

### FIELD

The present disclosure relates generally to semiconductor devices, and more particularly to transistor devices.

### BACKGROUND

Power semiconductor devices are widely used to carry large currents, support high voltages and/or operate at high frequencies such as radio frequencies. A wide variety of power semiconductor devices are available for different applications including, for example, power switching devices and power amplifiers. Many power semiconductor devices are implemented using various types of field effect transistors (FETs) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc.

Power semiconductor devices may be fabricated from wide bandgap semiconductor materials (e.g., having a bandgap greater than 1.40 eV). For example, power HEMTs may be fabricated from gallium nitride (GaN) or other Group III nitride-based material systems that are formed, for instance, on a silicon carbide (SiC) substrate or other substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide bandgap semiconductor materials such as silicon carbide (e.g., 2.996 eV bandgap for alpha silicon carbide at room temperature) and the Group III-nitrides (e.g., 3.36 eV bandgap for gallium nitride at room temperature) may provide higher electric field breakdown strengths and higher electron saturation velocities as compared to gallium arsenide (GaAs) and silicon (Si) based devices.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device includes a wide bandgap semiconductor structure. The semiconductor device includes a metal structure on the wide bandgap semiconductor structure. The metal structure has a metal layer, the metal layer has a metal selected from the group consisting of ruthenium, osmium, rhodium, or iridium.

Another example aspect of the present disclosure is directed to a transistor device. The transistor device includes a substrate. The transistor device includes a Group III-nitride semiconductor structure on the substrate. The Group III-nitride semiconductor structure includes a barrier layer and a channel layer. The barrier layer has a different bandgap relative to the channel layer. The transistor device includes a gate contact, source contact, and a drain contact. The gate contact is between the source contact and the drain contact. The gate contact includes a plurality of gate stack layers. At least one of the gate stack layers is a metal layer. The metal layer includes a metal selected from the group consisting of ruthenium, osmium, rhodium, or iridium.

Another example aspect of the present disclosure is directed to a method of forming a semiconductor device. The method includes forming a wide bandgap semiconductor structure on a substrate; and forming a gate contact on the wide bandgap semiconductor structure. The gate contact includes a metal layer. The metal layer includes a metal selected from the group consisting of ruthenium, osmium, rhodium, or iridium.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which.

FIG. 1 depicts a cross-sectional view of an example transistor device according to example embodiments of the present disclosure;

FIG. 2 depicts a simplified view of a gate structure having multiple layers and a semiconductor structure according to example embodiments of the present disclosure;

FIG. 3 depicts a simplified view of a gate structure having multiple layers and a semiconductor structure according to example embodiments of the present disclosure;

FIG. 4 depicts a simplified view of a gate structure having multiple layers and a semiconductor structure according to example embodiments of the present disclosure;

FIG. 5 depicts a cross-sectional semiconductor device according to example embodiments of the present disclosure;

FIG. 6 depicts a cross-sectional view of a semiconductor device according to example embodiments of the present disclosure;

FIG. 7 depicts a cross-sectional view of a semiconductor device according to example embodiments of the present disclosure;

FIG. 8 depicts a flow diagram of an example method according to example embodiments of the present disclosure;

FIG. 9 depicts a flow diagram of an example method according to example embodiments of the present disclosure.

FIG. 10 depicts peak current density of example transistor devices having a gate structure with ruthenium relative to a transistor device having a gate stack with nickel.

FIG. 11 depicts gate lag of example transistor devices having a gate structure with ruthenium relative to a transistor device having a gate stack with nickel.

FIG. 12 depicts a metal structure including nickel after exposure to chlorine.

FIG. 13 depicts a metal structure including ruthenium after exposure to chlorine.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Transistor devices, such as high electron mobility transistors (HEMTs), may be used in power electronics applications. HEMTs fabricated in Group III nitride-based material systems may have the potential to generate large amounts of radio frequency (RF) power because of the combination of material characteristics that includes high breakdown fields, wide bandgaps, large conduction band offset, and/or high saturated electron drift velocity. As such, Group III nitride based HEMTs may be promising candidates for high frequency and/or high-power RF applications, as well as for low frequency high power switching applications, both as discrete transistors or as coupled with other circuit elements, such as in monolithic microwave integrated circuit (MMIC) devices.

Transistor devices such as HEMT devices may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Often, high performance Group III nitride-based HEMT devices may be implemented as depletion mode (normally-on) devices, in that they are conductive at a gate-source bias of zero due to the polarization-induced charge at the interface of the barrier and channel layers of the device.

When an HEMT device is in an ON-state, a two-dimensional electron gas (2DEG) is formed at the heterojunction of two semiconductor materials with different bandgap energies, where the smaller bandgap material has a higher electron affinity. The 2DEG is an accumulation layer in the smaller bandgap material and can include a very high sheet electron concentration. Additionally, electrons that originate in the wider-bandgap semiconductor material transfer to the 2DEG layer, allowing high electron mobility due to reduced ionized impurity scattering. This combination of high carrier concentration and high carrier mobility may give the HEMT device a very large transconductance (which may refer to the relationship between output current and input voltage) and may provide a strong performance advantage over MOSFETs for high-frequency applications.

Semiconductor devices, such as HEMT devices, power MOSFETs, and Schottky diodes, may be exposed to various chemistries during fabrication. For instance, a semiconductor device may be exposed to a halide gas (e.g., chlorine gas or chlorine containing gas) to perform an etch process. Due to the volatile nature of the chemicals used, the chemical processes may cause unintended corrosion or contamination of components within the semiconductor device. For example, a chlorine-based etching process may lead to corrosion of a gate contact or other metal structure of the semiconductor device during the fabrication process. The corrosion of the gate contact or other metal structures may lead to reduced reliability of the semiconductor device and/or device failure.

According to example aspects of the present disclosure, a semiconductor device, such as a HEMT device, power MOSFET, and/or Schottky diode, may include a metal structure having a corrosion resistant material that is inert, for instance, to halide corrosion. The metal structure may include the corrosion resistant material to reduce corrosion or contamination during the fabrication process. For instance, the semiconductor device may include a gate contact, wherein the gate contact includes the corrosion resistant material. In some embodiments, the corrosion resistant material may be, for example, selected from a group consisting of ruthenium, iridium, osmium, or rhodium. In addition, or in the alternative, the semiconductor device may include a gate stack (e.g., metal stack) comprising a plurality of gate stack layers wherein one of the layers includes the corrosion resistant material (e.g., ruthenium, iridium, osmium, and/or rhodium).

In some embodiments, the corrosion resistant material may be used within a corrosion resistant layer of a gate stack. The gate stack may include multiple layers adhered together to form, for example, a gate contact. The gate stack may include a corrosion resistant layer including the corrosion resistant material. The corrosion resistant layer may be directly on the semiconductor structure of the semiconductor device (e.g., to provide a Schottky contact). The corrosion resistant layer may, for example, be ruthenium, iridium, osmium, or rhodium. The corrosion resistant layer may have a thickness of, for example, about 50 Angstroms to about 200 Angstroms. The gate stack may further include a conductive layer. For example, the gate stack may include the conductive layer on the corrosion resistant layer. The conductive layer may, for example, include gold. The conductive layer may have a thickness of, for example, about 1000 Angstroms to about 6000 Angstroms.

In some embodiments, the gate stack (e.g., metal stack) may include a diffusion barrier layer. The diffusion barrier layer may be between the conductive layer and the corrosion resistant layer. The diffusion barrier layer may include, for example, titanium. The diffusion barrier layer may have a thickness of, for example, 100 Angstroms to about 300 Angstroms. In some embodiments, the gate stack may include an adhesion layer. The adhesion layer may be between the conductive layer and the corrosion resistant layer. The adhesion layer may consist of, for example, platinum. The adhesion layer may have a thickness of, for example, about 50 Angstroms to about 300 Angstroms.

In accordance with example aspects of the present disclosure, the gate stack (e.g., metal stack) may include some or all the layers discussed herein. For example, the gate stack may include the corrosion resistant layer and the conductive layer. In another example, the gate stack may include the corrosion resistant layer, the diffusion barrier layer, and the conductive layer. In another example, the gate stack may include the corrosion resistant layer, the diffusion barrier layer, the adhesion layer, and the conductive layer. It should be appreciated that the layers of the gate stack may be rearranged, added, or eliminated without deviating from the scope of the present application.

In some embodiments, the corrosion resistant material is used to create a gate contact on a transistor device. The gate contact may be on a semiconductor structure of the transistor device. In some embodiments, the gate contact may form a Schottky contact with the semiconductor structure. In some embodiments, the semiconductor structure may be a wide bandgap semiconductor structure. Herein, a wide bandgap semiconductor material refers to a semiconductor material having a bandgap greater than 1.40 eV and may include, for instance, silicon carbide and/or a Group III-nitride.

Aspects of the present disclosure are discussed with reference to a gate structure having a corrosion resistant layer for purposes of illustration and discussion. Those of ordinary skill in the art, using the disclosures provided herein, will understand that other metal structures of a semiconductor device may include the corrosion resistant layer without deviating from the scope of the present disclosure.

Aspects of the present disclosure provide a number of technical effects and benefits. For instance, the present inventors have discovered that gate contacts including ruthenium, iridium, osmium, or rhodium are resistant to halide-based corrosion, oxidation, and chlorine contamination. The reduction and elimination of corrosion and contamination within the gate contact of a transistor device improves gate lag and reliability of the overall transistor device itself. For instance, the use of corrosion resistant materials (e.g., ruthenium) in transistor devices (e.g., HEMT devices) may improve the reliability and performance of the transistor devices.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to an HEMT transistor device for purposes of illustration and discussion. Those of ordinary skill in the art, using the disclosures provided herein, will appreciate that certain aspects of the present disclosure may be applicable to other transistor devices without deviating from the scope of the present disclosure. For instance, aspects of the present disclosure may be implemented in any transistor having a field plate or other transistors devices with metal structures, such as silicon carbide-based MOSFETS and/or Schottky diodes.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

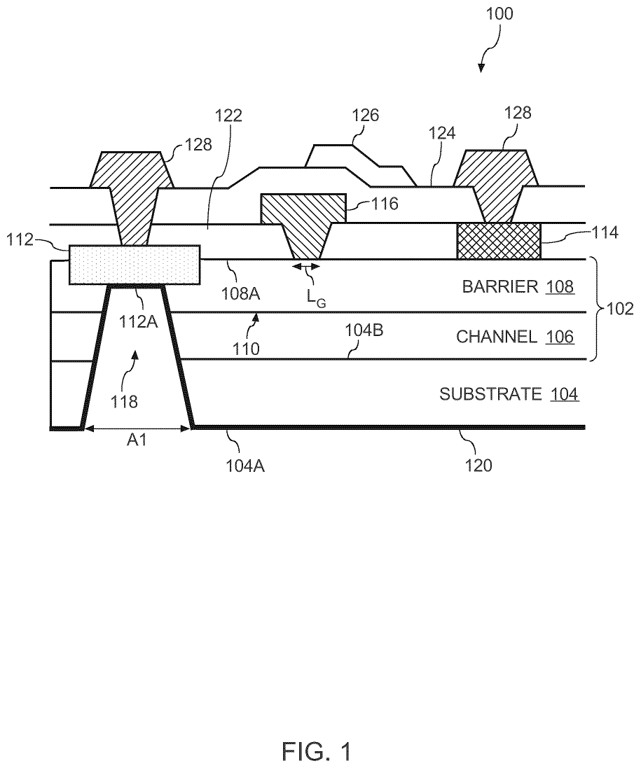

FIG. 1 depicts a cross-sectional view of an example HEMT device 100 according to example embodiments of the present disclosure. FIG. 1 is intended to represent structures for identification and description and is not intended to represent the structures to physical scale. The HEMT device 100 may include a semiconductor structure 102. The semiconductor structure 102 may be a Group III nitride semiconductor structure.

As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements can combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements. The semiconductor structure 102 may be metal-polar. However, aspects of the present disclosure are applicable to semiconductor devices having N-polar semiconductor structures without deviating from the scope of the present disclosure.

The semiconductor structure 102 may be on a substrate 104. The substrate 104 may be a semiconductor material. For instance, the substrate 104 may be a silicon substrate, a silicon carbide (SiC) substrate, a sapphire substrate, or other suitable substrate. In some embodiments, the substrate 104 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 104 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 104 may be a SiC wafer, and the HEMT device 100 may be formed, at least in part, via wafer-level processing, and the wafer may then be diced to provide a plurality of individual HEMT devices 100.

The substrate 104 may have a lower surface 104A and an upper surface 104B. In some embodiments, the substrate 104 of the HEMT device 100 may be a thinned substrate 104. In some embodiments, the thickness of the substrate 104 (e.g., in a vertical Z direction in FIG. 1) may be about 100 μm or less, such as about 75 μm or less, such as about 50 μm or less.

The HEMT device 100 may include a channel layer 106 on the upper surface 104B of the substrate 104 (or on the optional layers described further herein, such as an optional buffer layer or nucleation layer). The HEMT device 100 may include a barrier layer 108 on an upper surface of the channel layer 106. In some embodiments, the channel layer 106 and the barrier layer 108 may each be formed by epitaxial growth. Techniques for epitaxial growth of Group III nitrides have been described in, for example, U.S. Pat. Nos. 5,210,051, 5,393,993, and 5,523,589, the disclosures of which are incorporated by reference herein. The channel layer 106 may have a bandgap that is less than the bandgap of the barrier layer 108. The channel layer 106 may have a larger electron affinity than the barrier layer 108. The channel layer 106 and the barrier layer 108 may include Group III-nitride based materials.

In some embodiments, the channel layer 106 may be a Group III nitride, such as Al_{w}Ga_{1-w}N, where 0≤w<0.1, provided that the energy of the conduction band edge of the channel layer 106 is less than the energy of the conduction band edge of the barrier layer 108 at the interface between the channel layer 106 and barrier layer 108. In some embodiments, the aluminum mole fraction w is approximately 0, indicating that the channel layer 106 is GaN. The channel layer 106 may or may not include other Group III-nitrides such as InGaN, AlInGaN or the like. The channel layer 106 may be undoped (“unintentionally doped”) and may be grown to a thickness in the range of about 0.5 μm to about 5 μm, such as about 2 μm. The channel layer 106 may be a multi-layer structure, such as a superlattice or combinations of GaN, AlGaN or the like. The channel layer 106 may be under compressive strain in some embodiments.

The semiconductor structure 102 may include a barrier layer 108 on an upper surface of the channel layer 106. The barrier layer 108 may have a bandgap that is different from the bandgap of the channel layer 106. The energy of the conduction band edge of the barrier layer 108 may be greater than the energy of the conduction band edge of the channel layer 106 at the interface between the channel layer 106 and the barrier layer 108. The barrier layer 108 may be a Group III-nitride, such as AlₓGa₁₋ₓN, where x is the aluminum mole fraction in the barrier layer 108. In some embodiments, the aluminum mole fraction x is such that x is in a range of about 0.15 to about 0.40, such as about 0.20 to about 0.25, such as about 0.22 (e.g., the aluminum mole fraction is in a range of 15% to 40%, such as in a range of about 20% to about 25%, such as about 22%), indicating that the barrier layer is an AlGaN layer. The barrier layer 108 may include other Group III elements (e.g., In) without deviating from the scope of the present disclosure. The barrier layer 108, in some examples, may be a multilayer structure. The multilayer structure may include multiple Group III nitride-based layers with differing aluminum mole fractions. The barrier layer 108 may have a thickness in a range of about 10 Angstroms to about 300 Angstroms, such as about 120 Angstroms to about 170 Angstroms, such as about 150 Angstroms.

The channel layer 106 and/or the barrier layer 108 may be deposited, for example, by metal-organic chemical vapor deposition (MOCVD), molecular beam epitaxy (MBE), or hydride vapor phase epitaxy (HVPE). A 2DEG 110 may be induced in the channel layer 106 at an interface between the channel layer 106 and the barrier layer 108. The 2DEG 110 is highly conductive and allows conduction between the source and drain regions of the HEMT device 100.

While the HEMT device 100 is shown with a substrate 104, channel layer 106 and barrier layer 108 for purposes of illustration, the HEMT device 100 may include additional layers/structures/elements. For instance, the HEMT device 100 may include a buffer layer and/or nucleation layer(s) between substrate 104 and the channel layer 106. For example, an AlN buffer layer may be on the upper surface 104B of the substrate 104 to provide an appropriate crystal structure transition between a SiC substrate 104 and the channel layer 106. The optional buffer/nucleation/transition layers may be deposited by MOCVD, MBE, and/or HYPE.

The HEMT device 100 may include a cap layer on the barrier layer 108. HEMT structures including substrates, channel layers, barrier layers, and other layers are discussed by way of example in U.S. Pat. Nos. 5,192,987, 5,296,395, 6,316,793, 6,548,333, 7,544,963, 7,548,112, 7,592,211, 7,615,774, 7,709,269, 7,709,859 and 10,971,612, the disclosures of which are incorporated by reference herein. Additionally, strain balancing transition layer(s) may also and/or alternatively be provided as described, for example, in U.S. Pat. No. 7,030,428, the disclosure of which is incorporated by reference herein.

The HEMT device 100 may include a source contact 112 on an upper surface 108A of the barrier layer 108 or otherwise contacting the barrier layer 108. The HEMT device 100 may include a drain contact 114 on the upper surface 108A of the barrier layer 108 or otherwise contacting the barrier layer 108. The source contact 112 and the drain contact 114 may be laterally spaced apart from each other. In some embodiments, the source contact 112 and the drain contact 114 may include a metal that may form an ohmic contact to a Group III-nitride based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. In some embodiments, the source contact 112 may be an ohmic source contact 112. The drain contact 114 may be an ohmic drain contact 114. Thus, the source contact 112 and/or the drain contact 114 may include an ohmic contact portion in direct contact with the barrier layer 108. In some embodiments, the source contact 112 and/or the drain contact 114 may include a plurality of layers to form an ohmic contact that may be provided as described, for example, in U.S. Pat. Nos. 8,563,372 and 9,214,352, the disclosures of which are incorporated by reference herein.

The HEMT device 100 may include a gate contact 116 on the upper surface 108A of the barrier layer 108 or otherwise contacting the barrier layer 108 (e.g., recessed into the barrier layer 108). The gate contact 116 may have a gate length L_{G}. The gate length L_{G} may be the length of the gate contact 116 at the portion of the gate contact 116 that is on the semiconductor structure 102 as illustrated in FIG. 1. In some embodiments, the gate length L_{G} may be in the range of about 100 nm to about 400 nm, such as about 100 nm to about 350 nm. In some embodiments, the gate length L_{G} may be about 100 nm or less, such as about 90 nm or less, such as about 60 nm or less. In some embodiments, the gate length L_{G} may be in a range of about 40 nm to about 90 nm.

The material of the gate contact 116 may be chosen based on the composition of the barrier layer 108, and may, in some embodiments, be a Schottky contact. According to example embodiments, the gate contact 116 may include, for example, ruthenium, osmium, iridium, and/or rhodium.

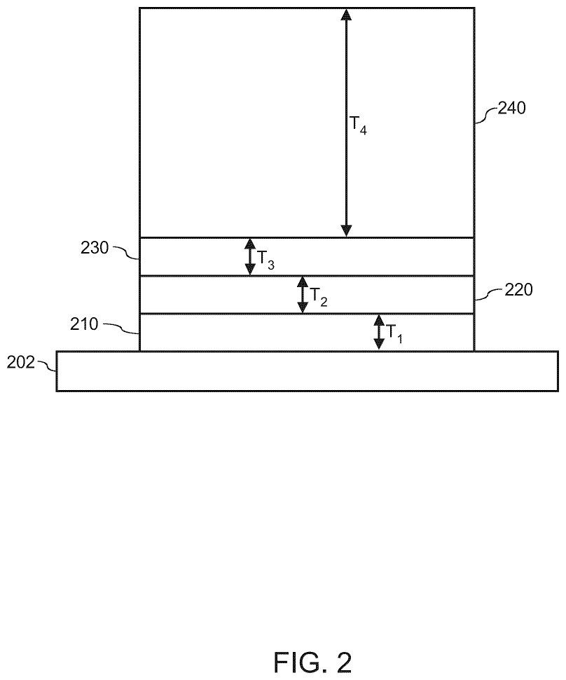

In some embodiments, the gate contact 116 may be a gate stack (e.g., metal stack) including a plurality of gate stack layers as depicted in FIGS. 2-4. For example, the gate contact 116 may include a corrosion resistant layer on the semiconductor device 102; a diffusion barrier layer on the corrosion resistant layer; an adhesion layer on the diffusion barrier layer; and a conductive layer the adhesion layer. In some embodiments, the corrosion resistant layer may be selected from the group consisting of ruthenium, osmium, iridium, and/or rhodium.

The source contact 112 may be coupled to a reference signal such as, for example, a ground voltage or other reference signal. The coupling to the reference signal may be provided by a via 118 that extends from a lower surface 104A of the substrate 104, through the substrate 104 and the channel layer 106 to the upper surface 108A of the barrier layer 108. The via 118 may expose a bottom surface of the ohmic portion 112A of the source contact 112. A back metal layer 120 may be on the lower surface 104A of the substrate 104 and on side walls of the via 118. The back metal layer 120 may directly contact the ohmic portion 112A of the source contact 112. In some embodiments a contact area between the back metal layer 120 and the bottom surface of the ohmic portion 112A of the source contact 112 may be fifty percent or more of an area of the bottom surface of the ohmic portion 112A of the source contact 112. Thus, the back metal layer 120, and a signal coupled thereto, may be electrically connected to the source contact 112.

In some embodiments, the via 118 may have an oval or circular cross-section when viewed in a plan view. However, the present disclosure is not limited thereto. In some embodiments, a cross-section of the via 118 may be a polygon or other shape, as will be understood by one of ordinary skill in the art using the disclosures provided herein. In some embodiments, dimensions of the via (e.g., a length and/or a width) may be such that a largest cross-sectional area Al of the via 118 is about 1000 μm² or less. The cross-sectional area Al may be taken in a direction that is parallel to the lower surface 104A of the substrate 104 (e.g., the X-Y plane of FIG. 1). In some embodiments, the largest cross-sectional area Al of the via 118 may be that portion of the via 118 that is adjacent the lower surface 104A of the substrate 104 (e.g., the opening of the via 118). For example, in some embodiments, a greatest width (e.g., in the X direction in FIG. 1) may be about 16 μm and a greatest length (e.g., in the Y direction in FIG. 1) may be about 40 μm, though the present disclosure is not limited thereto. In some embodiments, sidewalls of the via 118 may be inclined and/or slanted with respect to the lower surface 104A of the substrate 104. In some embodiments, the sidewalls of the via 118 may be approximately perpendicular to the lower surface 104A of the substrate 104.

Depending on the embodiment, the drain contact 114 may be formed on, in and/or through the barrier layer 108, and there can be ion implantation into the materials around the drain contact 114 (e.g., through the barrier layer 108 and into the channel layer 106) to reduce resistivity and provide improved ohmic contact to the semiconductor material. In yet other embodiments, there is no source via 118, and the source contact 112 is formed on, in and/or through the barrier layer 108, and there can be ion implantation in the materials around the source contact 112 to reduce resistivity and provide improved ohmic contact to the semiconductor material. In some examples, the connections to the source contact 112, drain contact 114, and/or gate contact 116 can be made from the top and/or the bottom to provide for flip chip configuration of the HEMT device 100. In some examples, thermal paths may be provided from the top and/or bottom to provide for flip chip configuration of the HEMT device 100.

The HEMT device 100 may include a first insulating layer 122. The first insulating layer 122 may directly contact the upper surface of the semiconductor structure 102 (e.g., contact the upper surface 108A of the barrier layer 108). The HEMT device 100 may include a second insulating layer 124. The second insulating layer 124 may be on the first insulating layer 122. It will also be appreciated that more than two insulating layers may be included in some embodiments. The first insulating layer 122 and/or the second insulating layer 124 may serve as passivation layers for the HEMT device 100. The first insulating layer 122 and/or the second insulating layer 124 may be dielectric layers. Different dielectric materials may be used such as a SiN, SiO2, Al₂O₃, MgOx, MgNx, ZnO, SiNx, SiOx, alloys or layer sequences thereof, or epitaxial materials.

The source contact 112, the drain contact 114, and the gate contact 116 may be in the first insulating layer 122. In some embodiments, at least a portion of the gate contact 116 may be on the first insulating layer 122. In some embodiments, the gate contact 116 may be a T-shaped gate and/or a gamma gate, the formation of which is discussed by way of example in U.S. Pat. Nos. 8,049,252, 7,045,404, and 8,120,064, the disclosures of which are incorporated by reference herein. The second insulating layer 124 may be on the first insulating layer 122 and on portions of the source contact 112, drain contact 114, and gate contact 116. The protrusions from the gate can also be referred to as a field plate integrated with the gate.

A field plate 126 may be on the second insulating layer 124 as illustrated in FIG. 1, or on another insulating layer depending on the number of insulating layers included in the HEMT device. At least a portion of a field plate 126 may be at least partially overlapping the gate contact 116. At least a portion of the field plate 126 may be on a portion of the second insulating layer 124 that is between the gate contact 116 and the drain contact 114. The field plate 126 may reduce the peak electric field in the HEMT device 100, which may result in increased breakdown voltage and reduced charge trapping. The reduction of the electric field can also yield other benefits such as reduced leakage currents and enhanced reliability. Field plates and techniques for forming field plates are discussed, by way of example, in U.S. Pat. No. 8,120,064, the disclosure of which is incorporated by reference herein.

Metal contacts 128 may be in or on the second insulating layer 124 as illustrated in FIG. 1, or on another insulating layer depending on the number of insulating layers included in the HEMT device. The metal contacts 128 may provide interconnection between the source contact 112 and other parts of the HEMT device 100, or may provide interconnection between the drain contact 114, and other parts of the HEMT device 100. Respective ones of the metal contacts 128 may directly contact respective ones of the drain contact 114 and/or source contact 112. The metal contacts 128 may include metal or other highly conductive material, including, for example, copper, cobalt, gold, and/or a composite metal.

A HEMT transistor may be formed by the active region between the source contact 112 and the drain contact 114 under the control of a gate contact 116 between the source contact 112 and the drain contact 114. FIG. 1 depicts a cross-sectional view of one unit of an HEMT device 100 for purposes of illustration. The HEMT device 100 may be formed adjacent to additional HEMT device units and may share, for instance, a source contact 112 with adjacent HEMT device units.

FIG. 2 depicts an example metal structure 200 according to example aspects of the present disclosure that may be used, for instance, in the HEMT device 100 of FIG. 1. FIG. 2 is intended to represent structures for identification and description and is not intended to represent the structures to physical scale. The metal structure 200 may be a gate stack (e.g., metal stack) and may include multiple layers 210, 220, 230, and 240 that together form, for example, a gate contact. The gate stack includes a first layer 210 on the semiconductor structure 202 of a semiconductor device. The first layer 210 may be a corrosion resistant layer. In some examples, the corrosion resistant layer may include a metal selected from the group consisting of ruthenium, osmium, rhodium, or iridium. The first layer 210 may have a thickness T1. The thickness T1 may be between, for example, about 50 Angstroms to about 200 Angstroms, such as between about 75 Angstroms to about 150 Angstroms.

In some embodiments, the metal structure 200 may include a second layer 220 on the first layer 210 of the metal structure 200. The second layer 220 may be a diffusion barrier layer. The diffusion barrier layer 220 may reduce diffusion of elements between multiple layers of the metal structure 200. The diffusion barrier layer may be, for example, titanium. The second layer 220 may have a thickness T2. The thickness T2 may be between, for example, about 100 Angstroms to about 300 Angstroms, such as between about 150 Angstroms to about 250 Angstroms.

In some embodiments, the metal structure 200 may include a third layer 230 on the second layer 220 of the metal structure 200. The third layer 230 may be an adhesion layer. The adhesion layer may facilitate adhesion of one or more layers of the metal structure 200 together. The third layer 230 (e.g., adhesion layer) may be, for example, platinum. The third layer 230 may have a thickness T3. The thickness T3 may be between, for example, about 50 Angstroms to about 300 Angstroms, such as between about 100 Angstroms to about 250 Angstroms.

In some embodiments, the metal structure 200 may include a fourth layer 240 on the third layer 230 of the metal structure 200. The fourth layer 240 may be a conductive layer. The fourth layer (e.g., conductive layer) may be, for example, gold or other suitable conductive material (e.g., copper, silver, etc.). In some embodiments, the fourth layer 240 may have a thickness T4. The thickness T4 may be between, for example, about 1000 Angstroms to about 6000 Angstroms, such as between about 2000 Angstroms and about 4500 Angstroms. In some embodiments 200 the metal structure 200 does not include nickel.

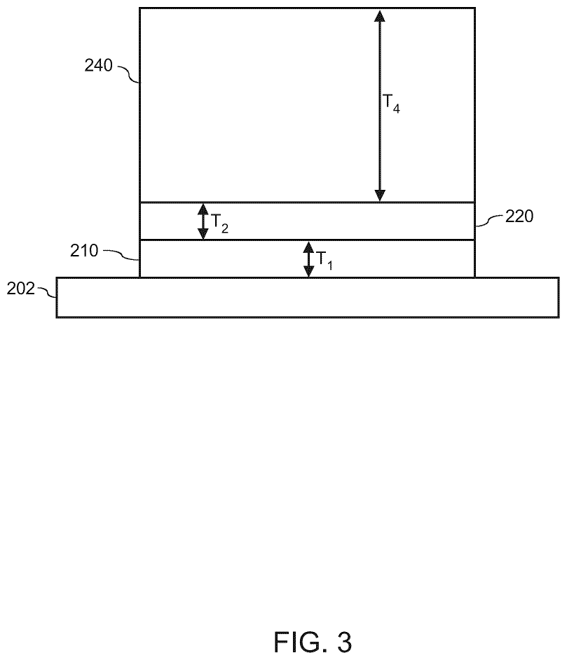

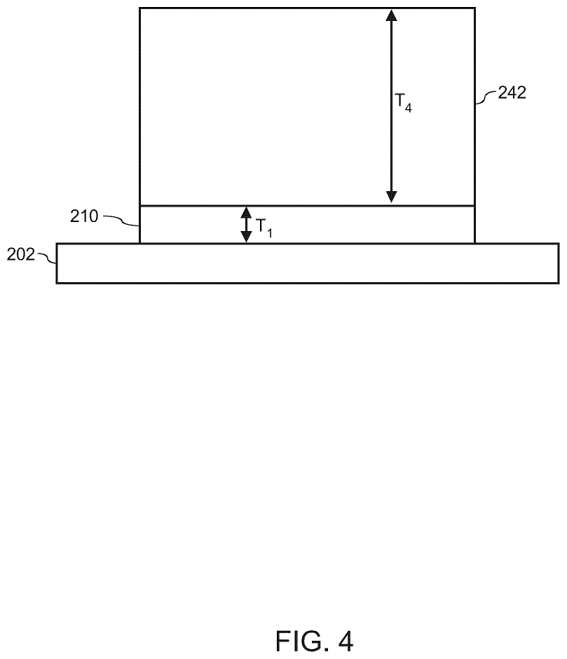

As described with reference to FIGS. 3-4, the layers of the metal structure 200 may be added, removed, or rearranged without deviating from the scope of the present disclosure. For example, as depicted in FIG. 3, the metal structure 200 may only include three layers to create the metal structure 300. The metal structure 300 may be on the semiconductor structure 202 and include the first layer 210, the second layer 220, and the fourth layer 240. In one example, the first layer 210 may be a corrosion resistant layer directly on the semiconductor structure 202, the second layer 220 may be a diffusion barrier layer directly on the first layer 210, and the fourth layer 240 may be a conductive layer onto the diffusion barrier layer.

In some examples, the metal structure 300 may include the first layer 210, the third layer 230, and the fourth layer 240 on the semiconductor structure 202. For example, the first layer 210 may be a corrosion resistant layer directly on the semiconductor structure 202, the third layer 230 may be an adhesion layer on the first layer 210, and the fourth layer 240 may be a conductive layer on the third layer 230.

FIG. 4 depicts an example where the metal structure 200 includes only two layers to create the metal structure 400. The metal structure 400 may include the first layer 210 and the fourth layer 240 on the semiconductor structure 202. For example, the first layer 210 may be a corrosion resistant layer placed directly on the semiconductor structure 202, and the fourth layer 240 may be a conductive layer placed on top of the first layer 210.

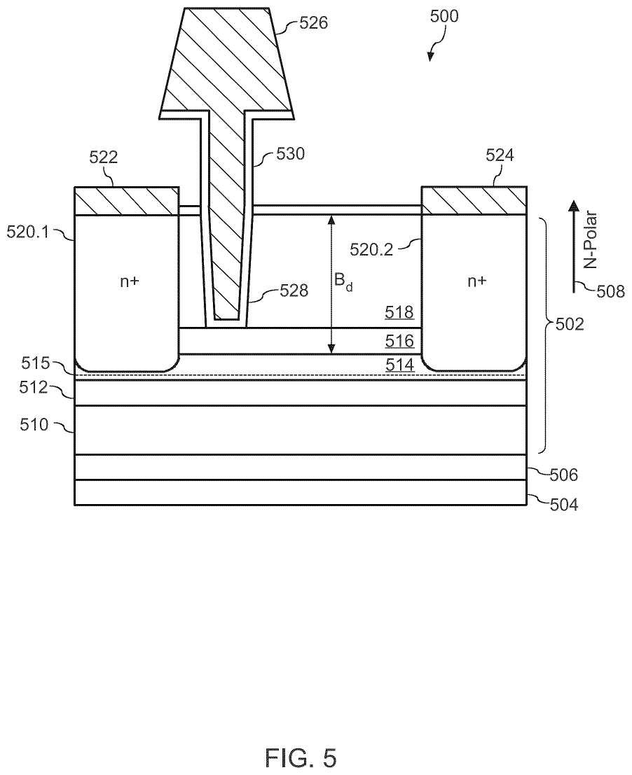

Aspects of the present disclosure are directed to other types of semiconductor devices that include a metal structure with a metal selected from the group consisting of ruthenium, osmium, iridium, and/or rhodium, such as N-polar HEMT devices, MOSFETs, Schottky diodes, etc. For instance, FIG. 5 depicts a cross-sectional view of an example HEMT device 500 according to example embodiments of the present disclosure. FIG. 5 is intended to represent structures for identification and description and is not intended to represent the structures to physical scale. The HEMT device 500 may include a semiconductor structure 502. The semiconductor structure 502 may be a Group III-nitride semiconductor structure, such as an N-polar Group III-nitride semiconductor structure.

The semiconductor structure 502 may be on a substrate 504. The substrate 504 may be a semiconductor material. For instance, the substrate 504 may be a silicon substrate, a silicon carbide (SiC) substrate, a sapphire substrate, or other suitable substrate. In some embodiments, the substrate 504 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 504 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 104 may be a SiC wafer, and the HEMT device 100 may be formed, at least in part, via wafer-level processing, and the wafer may then be diced to provide a plurality of individual HEMT devices 100. In some embodiments, the substrate 504 of the HEMT device 500 may be a thinned substrate 504. In some embodiments, the thickness of the substrate 504 may be about 100 μm or less, such as about 75 μm or less, such as about 50 μm or less.

The semiconductor structure 502 may include an optional nucleation layer 506 on the substrate 504. The nucleation layer 506 may be, for instance, a GaN layer and/or an AlN layer on the substrate 504 to provide a crystal structure transition between, for instance, a SiC substrate 104 and the Group III-nitride semiconductor structure 502. The nucleation layer 506 may be deposited on the substrate 504 using, for instance, metal-organic chemical vapor deposition (MOCVD), molecular beam epitaxy (MBE), or hydride vapor phase epitaxy (HVPE).

The semiconductor structure 502 may be an N-polar Group III-nitride semiconductor structure with an outward N-face in the growth direction 508 of the semiconductor structure 502. The semiconductor structure 502 may include several layers. In the example HEMT device 500 of FIG. 5, the semiconductor structure includes a buffer layer 510, a back barrier layer 512, a channel layer 514, a first cap layer 516, and a second cap layer 518. However, those of ordinary skill in the art, using the disclosures provided herein, will understand that aspects of the present disclosure are applicable to devices having semiconductor structures with different layer arrangements. The semiconductor structure 502 may be formed by epitaxial growth on the substrate 504. Techniques for epitaxial growth of Group III-nitrides have been described in, for example, U.S. Pat. Nos. 5,210,051, 5,393,993, and 5,523,589, the disclosures of which are incorporated by reference herein.

The buffer layer 510 may be an N-polar Group III nitride, such as AlᵥGa₁₋ᵥN, where 0≤v<0.1. In some embodiments, the aluminum mole fraction v is approximately 0 (e.g., 0.05 or less), indicating that the buffer layer 110 is GaN. The buffer layer 510 may or may not include other Group III-nitrides such as InGaN, AlInGaN or the like. The buffer layer 510 may be undoped or only unintentionally doped. In some examples, the buffer layer 510 may be iron doped to make the buffer layer semi-insulating. The buffer layer 510 may be grown to a thickness in the range of about 0.5 μm to about 5 μm, such as about 2 μm. The buffer layer 510 may be a multi-layer structure, such as a superlattice or combinations of GaN, AlGaN or the like. The buffer layer 510 may be under compressive strain in some embodiments.

The semiconductor structure 502 may include the back barrier layer 512 on the buffer layer 110. The back barrier layer 512 may be an N-polar Group III nitride, such as Al_{w}Ga_{1-w}N where 0.1≤w<0.4, indicating that the back barrier layer 512 is an AlGaN layer. In some embodiments, the back barrier layer 512 may be a ScAlN layer or a ScAlGaN layer. The back barrier layer 512 may or may not include other Group III-nitrides such as InGaN, AlInGaN or the like. The back barrier layer 512 may have a different band gap relative to the channel layer 514. The back barrier layer 512 may have a thickness in a range of about 250 Angstroms to about 350 Angstroms, such as about 300 Angstroms.

In some embodiments, the back barrier layer 512 may be a multilayer structure. For instance, in one example, the back barrier layer 512 may include a first layer of n+doped GaN with a thickness of about 100 Angstroms. The back barrier layer 512 may include a second layer of graded Al_{w.1}Ga_{1-w.1}N on the first layer, where w.1 varies from about 0.05 to about 0.4. The second layer of graded Al_{w}Ga_{1-w}N may have a thickness of about 100 Angstroms. The back barrier layer 512 may include a third layer of Al_{w.2}Ga_{1-w.2}N on the second layer, where w.2 is in a range of 0.3 to 0.4. The thickness of the third layer may be about 100 Angstroms. The back barrier layer 512 may include a fourth layer of AlN on the third layer. The thickness of the fourth layer may be in a range of about 5 Angstroms to about 15 Angstroms, such as about 7 Angstroms.

The semiconductor structure 502 may include the channel layer 514 on the back barrier layer 512. The channel layer 514 may be an N-polar Group III-nitride, such as AlₓGa₁₋ₓN, where 0≤x<0.1, provided that the energy of the conduction band edge of the channel layer 514 is less than the energy of the conduction band edge of the back barrier layer 512 at the interface between the channel layer 514 and the back barrier layer 512. The channel layer 514 may have a band gap that is different than the band gap of the back barrier layer 512. In some embodiments, the aluminum mole fraction x is approximately 0 (e.g., 0.05 or less), indicating that the channel layer 514 is GaN. The channel layer 514 may or may not include other Group III-nitrides such as InGaN, AlInGaN or the like. The channel layer 514 may have a thickness in a range of about 75 Angstroms to about 125 Angstroms, such as about 100 Angstroms.

A 2DEG 515 may be induced in the channel layer 514 at the interface between the channel layer 514 and the back barrier layer 512. The 2DEG 515 is highly conductive and allows conduction between the source and drain regions of the HEMT device 500. The 2DEG 515 may be controlled under operation of a gate, such that the HEMT device 500 acts as a controllable transistor device.

The semiconductor structure 502 includes a first cap layer 516 (e.g., an AlGaN cap layer) on the channel layer 514. The first cap layer 516 may be an N-polar Group III-nitride, such as Al_{y}Ga_{1-y}N where 0.1≤y<0.4, indicating that the first cap layer 516 is an AlGaN layer. In some embodiments, the aluminum mole fraction y is in a range of about 0.2 to about 0.3. In some embodiments, the first cap layer 516 may be a ScAlN layer or a ScAlGaN layer. The first cap layer 516 may or may not include other Group III-nitrides such as InGaN, AlInGaN or the like. The first cap layer may have a band gap that is different than the band gap of the channel layer 514. The first cap layer 516 may have a thickness in a range of about 15 Angstroms to about 50 Angstroms, such as about 26 Angstroms.

The semiconductor structure 502 includes a second cap layer 518 on the first confining layer 516. The second cap layer 518 may be an N-polar Group III-nitride, such as Al_{z}Ga_{1-z}N, where 0≤z<0.1. In some embodiments, the aluminum mole fraction z is approximately 0 (e.g., 0.05 or less), indicating that the second cap layer 518 is a GaN layer. The second cap layer 518 may or may not include other Group III-nitrides such as InGaN, AlInGaN or the like. The second cap layer 518 buries the channel layer 514 deep below the surface of semiconductor structure 502 such that the channel layer 514 is a buried layer at a depth of about 275 Angstroms or greater from the surface of the semiconductor structure 502, such as about 500 Angstroms or greater from the surface of the semiconductor structure 502, such as in a range of about 275 Angstroms to about 1000 Angstroms from the surface of the semiconductor structure 502. The second cap layer 518 may have a thickness in a range of about 250 Angstroms to about 1000 Angstroms, such as about 500 Angstroms.

The semiconductor structure 502 includes implanted regions 520.1 and 520.2. The implanted regions 520.1 and 520.2 include a distribution of implanted dopants (e.g., ions) of a first conductivity type such that the implanted regions 520.1 and 520.2 are n-type regions. The implanted regions 520.1 and 520.2 extend through the semiconductor structure 502 and into the channel layer 514.

The HEMT device 500 includes electrodes on the implanted regions 520.1 and 520.2. More particularly, the HEMT device 500 may include a source contact 522 on the implanted region 520.1. The HEMT device 500 may include a drain contact 524 on the implanted region 520.2. The source contact 522 and the drain contact 524 may be laterally spaced apart from each other. In some embodiments, the source contact 522 and the drain contact 524 may include a metal that may form an ohmic contact to a Group III-nitride based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. In some embodiments, the source contact 522 may be an ohmic contact. The drain contact 524 may be an ohmic contact. In some embodiments, the source contact 522 and/or the drain contact 524 may include a plurality of layers to form an ohmic contact that may be provided as described, for example, in U.S. Pat. Nos. 8,563,372 and 9,214,352, the disclosures of which are incorporated by reference herein.

The HEMT device 500 may include a gate contact 526. The gate contact 526 may extend at least partially through a trench (e.g., an ALE defined trench) in the cap layer 518 so that the gate contact 526 is proximate to the first cap layer 516. In some examples, the gate contact 526 may have a gate length L_{G} in a range of about 50 nm to about 150 nm. The gate length is the length of the gate contact 526 proximate to the first cap layer 516. In some embodiments, the gate contact 526 may include a corrosion resistant material, such as ruthenium, iridium, osmium, and/or rhodium. In some embodiments, the gate contact 526 may include a metal stack (e.g., gate stack) having multiple layers such as, for example, the metal stack(s) depicted in FIGS. 2-4. For instance, the gate contact 526 may include a metal stack including a corrosion resistant layer (e.g., ruthenium, iridium, osmium, and/or rhodium), a diffusion barrier layer (e.g., titanium), an adhesion layer (e.g., platinum), and a conductive layer (e.g., gold). In another instance, the metal stack may include a corrosion resistant layer including ruthenium, iridium, osmium, and/or rhodium and a conductive layer including gold.

A passivation layer 528 may be located between the gate contact 526 and the first cap layer 516. The passivation layer 528 may be SiN. Other suitable dielectric layers may be used as the passivation layer 528, such as SiO₂, MgOx, MgNx, ZnO, SiNx, SiOx or other dielectric layers. The passivation layer 528 may be formed, for instance, using MOCVD process(s), atomic layer deposition (ALD) process(s), and/or sputter deposition processes. The passivation layer 528 may serve as a gate dielectric. In some examples, the passivation layer 528 may have a thickness, for instance, of about 5 Angstroms to about 100 Angstroms, such as about 10 Angstroms to about 50 Angstroms.

The HEMT device 500 may include additional passivation layer(s) 530 on the semiconductor structure 502, the gate contact 526, and/or other structures of the HEMT device 500. The additional passivation layer(s) 530 may be, for instance, dielectric materials, such as SiO₂, MgOx, MgNx, ZnO, SiNx, SiOx, alloys or layer sequences thereof. The additional passivation layer(s) 530 may be formed using MOCVD process(s), ALD process(s), sputter deposition process(s), or other suitable process(s). One or more insulating layers (not shown) may be on the HEMT device 500. For instance, the HEMT device 500 may be encapsulated in an insulating material without deviating from the scope of the present disclosure.

In some examples, the HEMT device 500 may be operable at frequencies of up to about 150 GHz. For instance, the HEMT device 500 may be operable at a frequency in a range of about 10 GHz to about 150 GHz, such as in a range of about 30 GHz to about 150 GHz, such as in a range of about 50 GHz to about 150 GHz. In some examples, the HEMT device 500 may have a power density of up to 10 W/mm or greater in these frequency ranges, such as a power density in a range of 2.5 W/mm to about 12 W/mm.

A transistor device cell may be formed by the active region between the source contact 522 and the drain contact 524 under the control of a gate contact 526 between the source contact 522 and the drain contact 524. FIG. 5 depicts a cross-sectional view of one device cell of an HEMT device 500 for purposes of illustration.

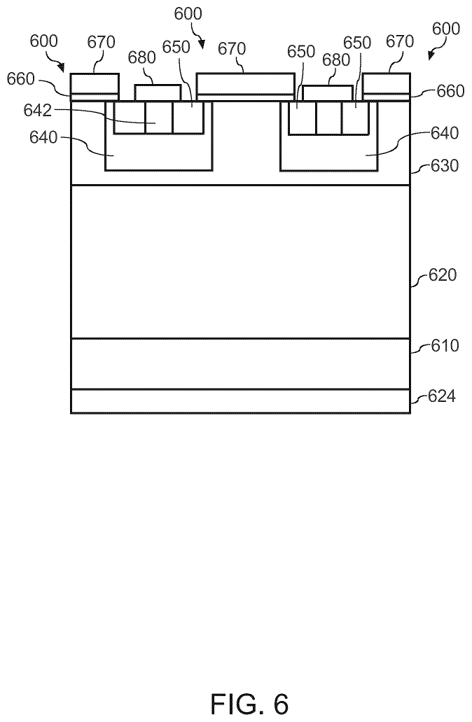

FIG. 6 is a schematic cross-sectional diagram of a MOSFET 600 according to example embodiments of the present disclosure. It will be appreciated that the specific layer structure, doping concentrations, materials, conductivity types and the like that are shown in FIG. 6 and/or described below are merely provided as examples to illustrate in detail the structure of a specific example embodiment. Thus, the specific details discussed below are not limiting to the present disclosure.

As shown in FIG. 6, the MOSFET 600 includes an n-type wide bandgap semiconductor substrate 610. The substrate 610 may include, for example, a single crystal 4H silicon carbide semiconductor substrate. The substrate 610 may be heavily-doped with n-type impurities (i.e., an n+ silicon carbide substrate). The impurities may comprise, for example, nitrogen or phosphorus. The doping concentration of the substrate 610 may be, for example, between 1×10¹⁸ atoms/cm³ and 1×10²¹ atoms/cm³, although other doping concentrations may be used. The substrate 610 may be any appropriate thickness (e.g., between 100 and 500 microns thick.

A lightly-doped n-type (n) silicon carbide drift region 620 is provided on the substrate 610. The n-type silicon carbide drift region 620 may be formed by, for example, epitaxial growth on the silicon carbide substrate 610. The n-type silicon carbide drift region 620 may have, for example, a doping concentration of 1×10¹⁶ to 5×10¹⁷ dopants/cm3. The n-type silicon carbide drift region 620 may be a thick region, having a vertical height above the substrate 610 of, for example, 3-100 microns. An upper portion of the n-type silicon carbide drift region 620 may comprise an n-type silicon carbide current spreading layer 630 in some embodiments. The n-type silicon carbide current spreading layer 630 may be grown in the same processing step as the remainder of the n-type silicon carbide drift region 620 and may be considered to be part of the n-type silicon carbide drift region 620. The n-type current spreading layer 630 may be a moderately-doped current spreading layer 630 that has a doping concentration (e.g., doping concentration of 1×10¹⁶ to 5×10¹⁸ dopants/cm³) that exceeds the doping concentration of the remainder of the more lightly-doped n-type silicon carbide drift region 620. The n-type current spreading layer 630 may be omitted in some embodiments.

An upper portion of the n-type current spreading layer 630 may be doped p-type by ion implantation to form p-wells 640. The p-wells 640 may have a doping concentration of, for example, between 5×10¹⁶/cm3 and 5×10¹⁹/cm3. An upper portion 642 of each p-well may be more heavily doped with p-type dopants. The upper portion 642 of each p-well 640 may have a doping concentration of, for example, between 2×10¹⁸/cm3 and 1×10²⁰/cm3. The p-wells 640 (including the more heavily-doped upper portions 642 thereof) may be formed by ion implantation. Ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer to a certain depth.

Heavily-doped (n+) n-type silicon carbide source regions 650 may be formed in upper portions of the p-wells 640 directly adjacent and contacting the more heavily doped portions 642 of the p-wells 640. The n-type source regions 650 may also be formed by ion implantation. The heavily-doped (n+) n-type silicon carbide source regions 650 act as source regions for the MOSFET transistor. The drift region 620/current spreading layer 630 and the substrate 610 together may act as a common drain region.

The n-type silicon carbide substrate 610, n-type silicon carbide drift region 220/current spreading layer 630, the p-wells 640, doped portions 642 and the n-type source regions 650 formed therein may together comprise a semiconductor structure of a semiconductor device.

A gate insulating pattern 660 may be formed on the upper surface of the semiconductor layer structure over the exposed portions of the current spreading layer 630 and extending onto the edges of the p-wells 640 and n-type source regions 650. The gate insulating pattern 660 may include, for example, a silicon oxide layer, although other insulating materials may be used. A gate contact 670 is formed on the gate insulating pattern 660.

In some instances, the gate contact 670 may include a corrosion resistant material such as, for example, ruthenium, osmium, rhodium, or iridium. In some embodiments, the gate contact 670 may include a metal stack (e.g., gate stack) having multiple layers. For example, the gate contact 670 may be a metal stack having a corrosion resistant layer (e.g., ruthenium, iridium, osmium, and/or rhodium), a diffusion barrier layer (e.g., titanium), an adhesion layer (e.g., platinum), and a conductive layer (e.g., gold). In another example, the gate contact 670 may be a metal stack including a corrosion resistant layer and a conductive layer.

Source contacts 680 may be formed on the heavily-doped n-type source regions 650 and the more heavily-doped portions 642 of the p-wells. The source contacts 680 may be part of a continuous source pattern that extends across the upper surface of the silicon carbide semiconductor layer structure. The source contacts 680 may include, for example, metals such as nickel, titanium, tungsten or aluminum, or alloys or thin layered stacks of these or similar materials. As described above, a drain contact 624 may be formed on the lower surface of the substrate 610. The drain contact 624 may include, for example, similar materials to the source contact, as this forms an ohmic contact to the silicon carbide substrate. While the MOSFET 600 is an n-type device with the source contacts 680 on an upper surface thereof and the drain contact 624 on the bottom surface thereof, it will be appreciated that in p-type devices these locations are reversed.

FIG. 6 depicts a MOSFET 600 with a gate contact 670 formed on top of the semiconductor structure for purposes of illustration and discussion. Alternatively, the MOSFET 600 may have the gate contact 670 at least partially in a gate trench within the semiconductor structure.

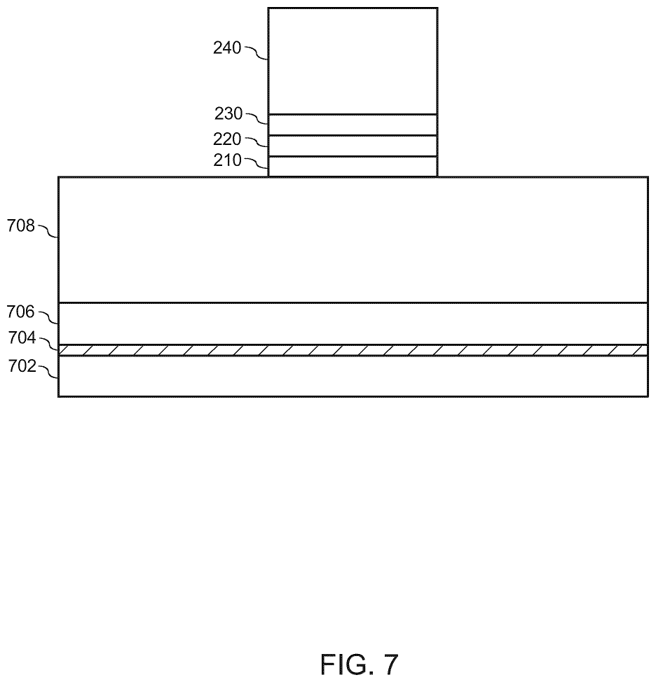

FIG. 7 depicts a Schottky diode 700 in accordance with example embodiments of the present disclosure. The Schottky diode 700 includes a cathode contact 702 on the bottom of the Schottky diode 700. The cathode contact 702 may be electrically coupled to a substrate 706 using a cathode ohmic layer 704. The substrate may include a drift layer 708 on the opposing side of the substrate 706 as the cathode contact 702. In some instances, the substrate 706 may be a silicon carbide substrate.

The Schottky diode 700 may include an anode stack (e.g., metal stack) on top of the drift layer 708 such as, for example, the metal stack(s) depicted in FIGS. 2-4. Like the metal stack depicted in FIG. 2, a first layer 210, second layer 220, third layer 230, and fourth layer 240 may be directly on the drift layer 708. For example, a corrosion resistant layer may be directly on the drift layer 708, a diffusion barrier layer on the corrosion resistant layer, an adhesion layer on the diffusion barrier layer, and a conductive layer on the adhesion layer to create the metal stack shown in FIG. 7. In one embodiment, the four layers may include ruthenium, platinum, titanium, and gold respectively. In another embodiment, the metal stack on the drift layer 708 may include the first layer 210, a corrosion resistant layer made of ruthenium, and the fourth layer 240, a conductive layer made of gold. As depicted in FIGS. 2-4, the metal stack on the drift layer 708 may have a variety of layers that may be added to, rearranged, or removed while remaining within the scope of the present disclosure.

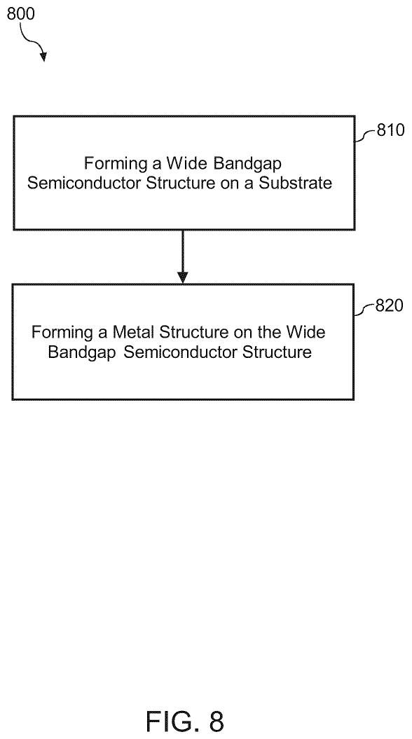

FIG. 8 depicts a method 800 of forming a semiconductor device according to example embodiments of the present disclosure. FIG. 8 depicts example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

At 810, the method includes forming a wide bandgap semiconductor structure on a substrate. In some examples, the wide bandgap semiconductor is a Group III-nitride. In one example, the substrate the semiconductor structure is formed on is a silicon carbide substrate. For instance, the semiconductor structure 102 may be formed on the substrate 104, for example, a silicon carbide substrate, as depicted in FIG. 1.

At 820, the method further includes forming a metal contact (e.g., a gate contact) on the wide bandgap semiconductor structure. In some instances, the metal contact includes a corrosion resistant layer comprising ruthenium, osmium, rhodium, and/or iridium. For example, the metal contact 116 may be formed on the semiconductor structure 102 and substrate 104 as depicted in FIG. 1. The corrosion resistant layer may have a thickness in a range of about 50 Angstroms to about 200 Angstroms. In some instances, the metal contact may include a plurality of layers, with at least one of the layers being the corrosion resistant layer.

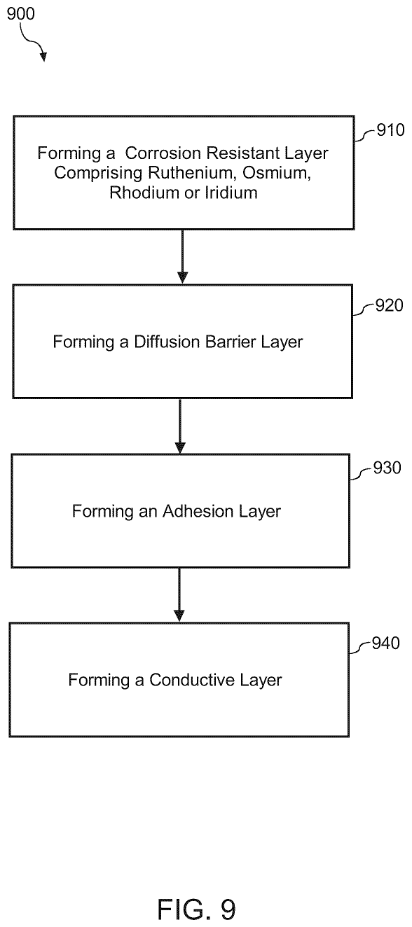

For example, FIG. 9 depicts a method 900 of forming a gate stack (e.g., metal stack) for a semiconductor device including a plurality of layers according to example embodiments of the present disclosure. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

At 910, the method includes forming a corrosion resistant layer. The corrosion resistant layer may include, for example, ruthenium, osmium, rhodium, or iridium. The corrosion resistant layer may have a thickness of, for example, about 50 Angstroms to about 200 Angstroms. For example, the first layer 210, a corrosion resistant layer, may be formed on the semiconductor structure 202 as depicted in FIG. 2.

At 920, the method includes forming a diffusion barrier layer made of, for example, titanium. In some instances, the diffusion barrier layer is formed on the corrosion resistant layer. The diffusion barrier layer may have a thickness of, for example, about 100 Angstroms to about 300 Angstroms. For example, the second layer 220, a diffusion barrier layer, may be formed on the first layer 210 and semiconductor structure 202 as depicted in FIG. 2

At 930, the method includes forming an adhesion layer made of, for example, platinum. In some instances, the adhesion layer is formed directly on top of the diffusion barrier layer. The adhesion layer may have a thickness of, for example, about 50 Angstroms to about 300 Angstroms. For example, the third layer 230, an adhesion layer, may be formed on the second layer 220 and first layer 210 as depicted in FIG. 2.

At 940, the method includes forming a conductive layer made of, for example, gold. In some instances, the conductive layer may be formed directly on top of the adhesion layer. The conductive layer may have a thickness of, for example, about 1000 Angstroms to about 6000 Angstroms. For example, the fourth layer 240, a conductive layer, may be formed on the third layer 230, second layer 220, and first layer 210 as depicted in FIG. 2.

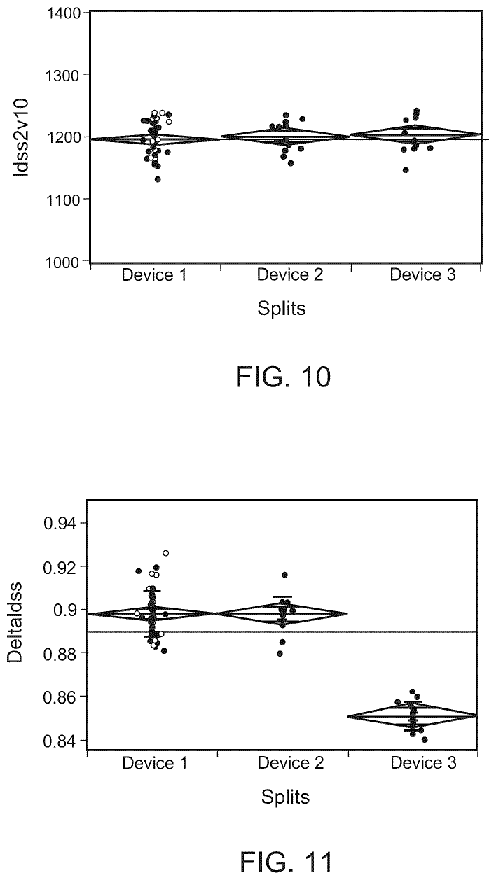

FIG. 10 depicts a comparison of peak current density of example transistor devices having a gate structure with ruthenium relative to a transistor device having a gate stack with nickel. FIG. 10 plots current density IDSS² for three devices. Devices 1 and 2 have a gate stack with a ruthenium layer of about 100 Angstroms and a titanium layer of about 100 Angstroms. Device 2 has been subjected to an anneal process. Device 3 has a metal stack including nickel. As demonstrated in FIG. 10, the peak current density for devices including a metal stack with ruthenium (e.g., Device 1 and Device 2) is substantially the same as the peak current density for devices that include nickel (e.g., Device 3).

FIG. 11 depicts gate lag of example transistor devices having a gate structure with ruthenium relative to a transistor device having a gate stack with nickel. FIG. 11 plots gate lag for three devices. Devices 1 and 2 have a gate stack with a ruthenium layer of about 100 Angstroms and a titanium layer of about 100 Angstroms. Device 2 has been subjected to an anneal process. Device 3 has a metal stack including nickel. As demonstrated in FIG. 11, the gate lag for devices including a metal stack with ruthenium (e.g., Device 1 and Device 2) provides about a 5% improvement relative to devices that include nickel (e.g., Device 3).

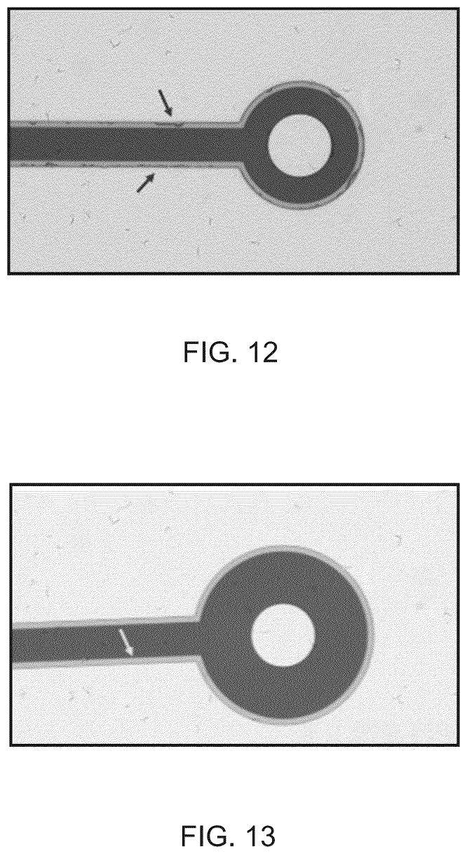

FIG. 12 depicts a metal structure including nickel after exposure to chlorine. The arrows indicate corrosion on the metal structure. FIG. 13 depicts a metal structure including ruthenium after the same exposure to chlorine. As demonstrated in FIG. 13, the corrosion of the metal structure is reduced.

Example aspects of the present disclosure are set forth below. Any of the below features or examples may be used in combination with any of the embodiments or features provided in the present disclosure.

One example aspect of the present disclosure is directed to a semiconductor device. The semiconductor device includes a wide bandgap semiconductor structure. The semiconductor device includes a metal structure on the wide bandgap semiconductor structure. The metal structure has a metal layer, the metal layer has a metal selected from the group consisting of ruthenium, osmium, rhodium, or iridium.

In some examples, the metal is ruthenium.

In some examples, the metal is osmium.

In some examples, the metal is rhodium.

In some examples, the metal is iridium.

In some examples, the metal structure is a Schottky contact with the wide bandgap semiconductor structure.

In some examples, the metal structure is a gate contact on the wide bandgap semiconductor structure.

In some examples, a thickness of the metal layer is in a range of about 50 Angstroms to about 200 Angstroms.

In some examples, the metal structure further comprises an adhesion layer.

In some examples, the adhesion layer comprises platinum.

In some examples, a thickness of the adhesion layer is about 50 Angstroms to about 300 Angstroms.

In some examples, the metal structure further comprises a diffusion barrier layer.

In some examples, the diffusion barrier layer comprises titanium.

In some examples, a thickness of the diffusion barrier layer is about 100 Angstroms to about 300 Angstroms.

In some examples, the metal structure further comprises a conductive layer.

In some examples, the conductive layer comprises gold.

In some examples, a thickness of the conductive layer is about 1000 Angstroms to about 6000 Angstroms.

In some examples, the metal structure does not include nickel.

In some examples, the wide bandgap semiconductor structure comprises a Group III-nitride.

In some examples, the Group III-nitride is an N-polar Group III-Nitride.

In some examples, the wide bandgap semiconductor structure further comprises a barrier layer, a channel layer, and a two-dimensional electron gas (2DEG) at an interface between the channel layer and the barrier layer.

In some examples, the channel layer comprises Al_{w}Ga_{1-w}N, where w is 0≤w<0.1, wherein the barrier layer comprises AlₓGa₁₋ₓN, where x is 0.1≤x 0.4.

In some examples, the wide bandgap semiconductor structure is on a substrate, the substrate comprising silicon carbide.

In some examples, the semiconductor device is a high electron mobility transistor.

In some examples, the semiconductor device is a Schottky diode.

In some examples, the semiconductor device is a MOSFET.

Another example aspect of the present disclosure is directed to a transistor device. The transistor device includes a substrate. The transistor device includes a Group III-nitride semiconductor structure on the substrate. The Group III-nitride semiconductor structure includes a barrier layer and a channel layer. The barrier layer has a different bandgap relative to the channel layer. The transistor device includes a gate contact, source contact, and a drain contact. The gate contact is between the source contact and the drain contact. The gate contact includes a plurality of gate stack layers. At least one of the gate stack layers is a metal layer. The metal layer includes a metal selected from the group consisting of ruthenium, osmium, rhodium, or iridium.

In some examples, the metal is ruthenium.

In some examples, the metal is osmium.

In some examples, the metal is rhodium.

In some examples, the metal is iridium.

In some examples, the transistor device further comprises a field plate wherein at least a portion of the field plate overlaps the gate contact.

In some examples, the metal layer contacts the Group III-nitride semiconductor structure.

In some examples, a thickness of the metal layer is in a range of about 50 Angstroms to about 200 Angstroms.

In some examples, the plurality of gate stack layers further comprises an adhesion layer.

In some examples, the adhesion layer comprises platinum.

In some examples, a thickness of the adhesion layer is about 50 Angstroms to about 300 Angstroms.

In some examples, the plurality of gate stack layers further comprises a diffusion barrier layer.

In some examples, the diffusion barrier layer comprises titanium.

In some examples, a thickness of the diffusion barrier layer is about 100 Angstroms to about 300 Angstroms.

In some examples, the plurality of gate stack layers further comprises a conductive layer.

In some examples, the conductive layer comprises gold.

In some examples, a thickness of the conductive layer is about 1000 Angstroms to about 6000 Angstroms.

In some examples, the gate contact does not include nickel.

In some examples, the Group III-nitride semiconductor structure further comprises a two-dimensional electron gas (2DEG) at an interface between the channel layer and the barrier layer.

In some examples, the Group III-nitride semiconductor structure is an N-polar Group III-Nitride semiconductor.

In some examples, the transistor device includes field plate.

In some examples, the channel layer comprises Al_{w}Ga_{1-w}N, where w is 0≤w<0.1, wherein the barrier layer comprises AlₓGa₁₋ₓN, where x is 0.1<x<0.4.

In some examples, the substrate comprises silicon carbide.

Another example aspect of the present disclosure is directed to a method of forming a transistor device. The method includes forming a wide bandgap semiconductor structure on a substrate; and forming a gate contact on the wide bandgap semiconductor structure. The gate contact includes a metal layer. The metal layer includes a metal selected from the group consisting of ruthenium, osmium, rhodium, or iridium.

In some embodiments, the metal is ruthenium.

In some embodiments, the metal is osmium.

In some embodiments, the metal is rhodium.

In some embodiments, the metal is iridium.

In some embodiments, a thickness of the metal layer is in a range of about 50 Angstroms to about 200 Angstroms.

In some embodiments, forming a gate contact on the wide bandgap semiconductor structure further comprises forming an adhesion layer.

In some embodiments, the adhesion layer comprises platinum.

In some embodiments, a thickness of the adhesion layer is about 50 Angstroms to about 300 Angstroms.

In some embodiments, forming a gate contact on the wide bandgap semiconductor structure further comprises forming a diffusion barrier layer.

In some embodiments, the diffusion barrier layer comprises titanium.

In some embodiments, a thickness of the diffusion barrier layer is about 100 Angstroms to about 300 Angstroms.

In some embodiments, forming a gate contact on the wide bandgap semiconductor structure further comprises forming a conductive layer.

In some embodiments, the conductive layer comprises gold.

In some embodiments, a thickness of the conductive layer is about 1000 Angstroms to about 6000 Angstroms.

In some embodiments, the substrate comprises silicon carbide.

In some embodiments, the wide bandgap semiconductor structure is a Group III-Nitride semiconductor structure.

In some embodiments, the semiconductor device is a high electron mobility transistor.

In some embodiments, the semiconductor device is a Schottky diode.

In some embodiments, the semiconductor device if a MOSFET.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a wide bandgap semiconductor structure;
a metal structure on the wide bandgap semiconductor structure; and
wherein the metal structure comprises a metal layer, the metal layer comprising a metal selected from the group consisting of ruthenium, osmium, rhodium, or iridium.

2. The semiconductor device of claim 1, wherein the metal is ruthenium.

3. The semiconductor device of claim 1, wherein the metal is osmium.

4. The semiconductor device of claim 1, wherein the metal is rhodium.

5. The semiconductor device of claim 1, wherein the metal is iridium.

6. The semiconductor device of claim 1, wherein the metal structure is a Schottky contact with the wide bandgap semiconductor structure.

7. The semiconductor device of claim 1, wherein the metal structure is a gate contact on the wide bandgap semiconductor structure.

8. The semiconductor device of claim 1, wherein a thickness of the metal layer is in a range of about 50 Angstroms to about 200 Angstroms.

9. The semiconductor device of claim 1, wherein the metal structure further comprises an adhesion layer, wherein the adhesion layer comprises platinum, wherein a thickness of the adhesion layer is about 50 Angstroms to about 300 Angstroms,

10-11. (canceled)

12. The semiconductor device of claim 1, wherein the metal structure further comprises a diffusion barrier layer, wherein the diffusion barrier layer comprises titanium, wherein a thickness of the diffusion barrier layer is about 100 Angstroms to about 300 Angstroms.

13.-14. (canceled)

15. The semiconductor device of claim 1, wherein the metal structure further comprises a conductive layer, wherein the conductive layer comprises gold, wherein a thickness of the conductive layer is about 1000 Angstroms to about 6000 Angstroms.

16.-17. (canceled)

18. The semiconductor device of claim 1, wherein the metal structure does not include nickel.

19. The semiconductor device of claim 1, wherein the wide bandgap semiconductor structure comprises a Group III-nitride.

20. (canceled)

21. The semiconductor device of claim 19, wherein the wide bandgap semiconductor structure further comprises a barrier layer, a channel layer, and a two-dimensional electron gas (2DEG) at an interface between the channel layer and the barrier layer.

22. (canceled)

23. The semiconductor device of claim 21, wherein the wide bandgap semiconductor structure is on a substrate, the substrate comprising silicon carbide.

24. The semiconductor device of claim 1, wherein the semiconductor device is a high electron mobility transistor.

25. The semiconductor device of claim 1, wherein the semiconductor device is a Schottky diode.

26. The semiconductor device of claim 1, wherein the semiconductor device is a MOSFET.

27. A transistor device, comprising:
a substrate;
a Group III-nitride semiconductor structure on the substrate, the Group III-nitride semiconductor structure comprising a barrier layer and a channel layer, the barrier layer having a different bandgap relative to the channel layer;
a gate contact, source contact, and a drain contact, wherein the gate contact is between the source contact and the drain contact; and
wherein the gate contact comprises a plurality of gate stack layers, wherein at least one of the gate stack layers is a metal layer comprising a metal selected from the group consisting of ruthenium, osmium, rhodium, or iridium.

28.-49. (canceled)

50. A method of forming a semiconductor device, comprising:
forming a wide bandgap semiconductor structure on a substrate;
forming a gate contact on the wide bandgap semiconductor structure; and
wherein the gate contact comprises a metal layer, the metal layer comprising a metal selected from the group consisting of ruthenium, osmium, rhodium, or iridium.

51.-69. (canceled)
